(19) United States
(12) Patent Application Publication
(10) Pub. No.: US 2002/0137305 A1
(43) Pub. Date: Sep. 26, 2002

(54) Fabrication method of shallow trench isolation

(76) Inventors: Bih-Tiao Lin, Ping-Tung Hsien (TW); Chingfu Lin, Taipei (TW)

Correspondence Address: J.C. Patents, Suite 250, 4 Venture, Irvine, CA, 92618, US

(21) Appl. No.: 10/055,157

(22) Filed: Oct. 22, 2001

Related U.S. Application Data
(63) Continuation-in-part of application No. 09/371,678, filed on Aug. 10, 1999, now abandoned.

(30) Foreign Application Priority Data
Jun. 17, 1999 (TW) 88110182

(51) Int. Cl. H01L 21/76

(52) U.S. Cl. 438/424

(57) ABSTRACT

A fabrication method is offered for shallow trench isolation structures. The insulating layer is deposited in trenches and on a mask layer on a substrate. The thickness of the insulating layer in the trenches is between the depth of the trenches and the depth of the trenches plus the thickness of the mask layer. Then, the thin layer is formed on the insulating layer. The screen layer is formed on the thin layer above the trenches to protect the thin layer when the thin layer and the insulating layer above active areas are removed. Next, the thin layer above the trenches and the mask layer are removed.

### CROSS-REFERENCE TO RELATED APPLICATION

This application claims the priority benefit of Taiwan application serial no. 88110182, filed Jun. 17, 1999, the full disclosure of which is incorporated herein by reference. This Application is a continuation-in-part (CIP) of the prior patent application Ser. No. 09/371,678 filed on Aug. 10, 1999.

### BACKGROUND OF THE INVENTION

1. Field of Invention

The present invention relates to fabrication of a semiconductor device. More particularly, the present invention relates to fabrication of shallow trench isolation (STI).

2. Description of Related Art

Device isolation technology is an important process in integrated circuit (IC) fabrication for electrically isolating the various active components in the IC. As integration becomes higher, isolation becomes more difficult. A conventional method for device isolation is known as the local oxidation of silicon (LOCOS) technique, which is used to provide field oxide to serve as isolation structures in the integrated circuit. One drawback to the LOCOS technique, however, is that the resulting isolation structure has a bird's beak shape that makes the further downsizing of the IC device difficult to realize. The STI technique serves as a solution to the drawback of the LOCOS technique, and is now widely used in sub-half micron semiconductor fabrication.

The conventional STI process uses the silicon nitride as a hard mask when anisotropically etching the semiconductor substrate to form a trench. The trench is filled with silicon oxide to serve as a device isolation structure. Chemical mechanical polishing (CMP) is used to planarize the STI; therefore, the surface of STI is coplanar with the semiconductor substrate.

Some silicon oxide particles or environmental dust particles always fall on the substrate. Hence during the CMP process, many micro-scratches or defects are formed on the surface of the oxide plug. In addition, CMP is a costly process.

### SUMMARY OF THE INVENTION

As embodied and broadly described herein, the invention provides a fabrication method of shallow trench isolation without using CMP. There are active areas on the substrate, and trenches are formed to isolate these active areas. A mask layer is formed on these active areas. An insulating layer is formed in trenches and on the mask layer, and a surface level of the insulating layer in trenches is no lower than that of the substrate and no higher than that of the mask layer. A thin layer is formed on the insulating layer. A screen layer is formed on the thin layer above trenches. The thin layer and the insulating layer on the mask layer are sequentially removed. Then the screen layer and the thin layer on the trenches and the mask layer on the active areas are removed to form STI in the substrate. The STI has a planar surface, which is about level with the substrate surface.

The formation method of the insulating layer mentioned above is, for example, high density plasma chemical vapor deposition (HDPCVD). The high density plasma of HDPCVD has a bombarding effect; therefore the insulating layer has vertical side wall above the edge of the active areas. The screen layer is formed by, for example, floatable precursors. The floatable precursor fills up the low-lying place, i.e., above the trenches, to protect the thin layer above trenches. Hence, when the thin layer and the insulating layer above the active areas are removed, the insulating layer above the trenches is not hurt.

This invention deposits the insulating layer in the trenches and on the mask layer. The thickness of the insulating layer in the trenches is between the trench depth and the trench depth plus the mask layer thickness. Then, the thin layer is formed on the insulating layer. The screen layer is formed on the thin layer above the trenches to protect it when the thin layer and the insulating layer above the active areas are removed. Next, the thin layer above the trenches and the mask layer are removed. Hence, this invention provides a method of fabricating STI without using CMP. The STI obtained have planar surfaces without scratches or defects thereon.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A-1F are cross-sectional views of a semiconductor device schematically illustrating a fabrication process for forming a shallow trench isolation structure, according to a preferred embodiment of the invention.

### DESCRIPTION OF THE PREFERRED EMBODIMENTS

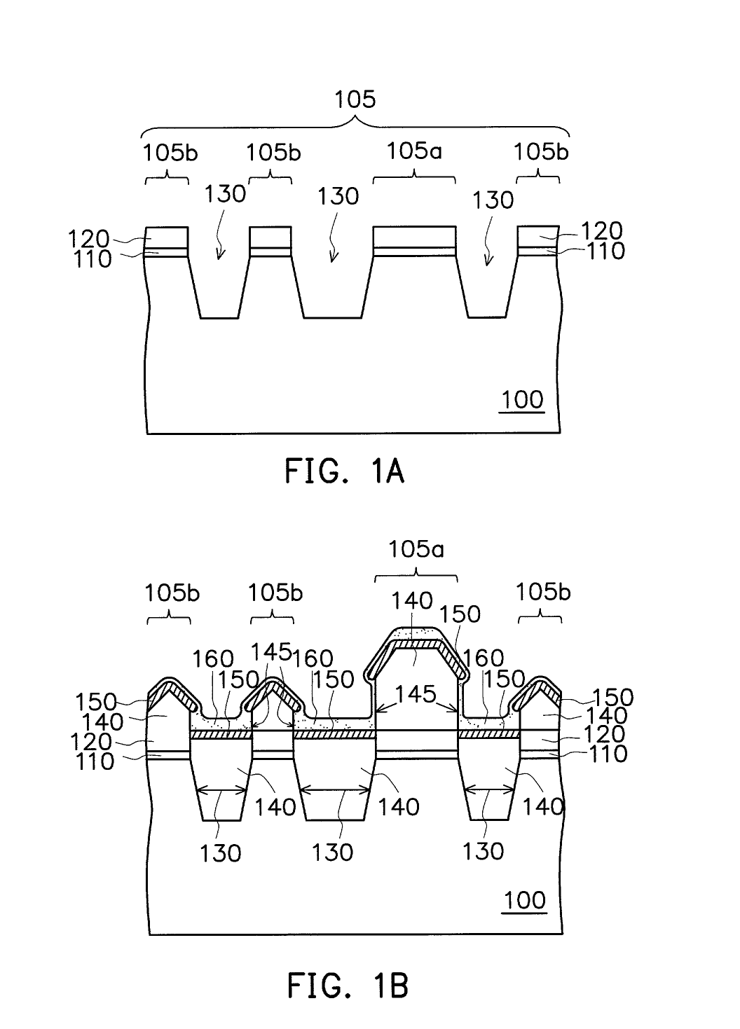

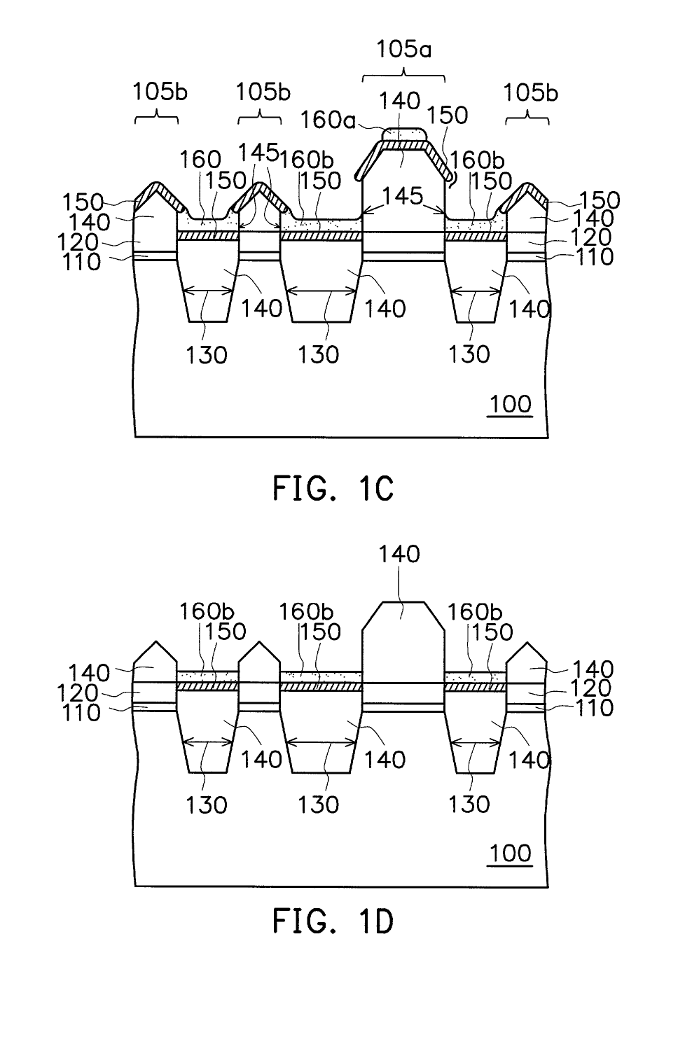

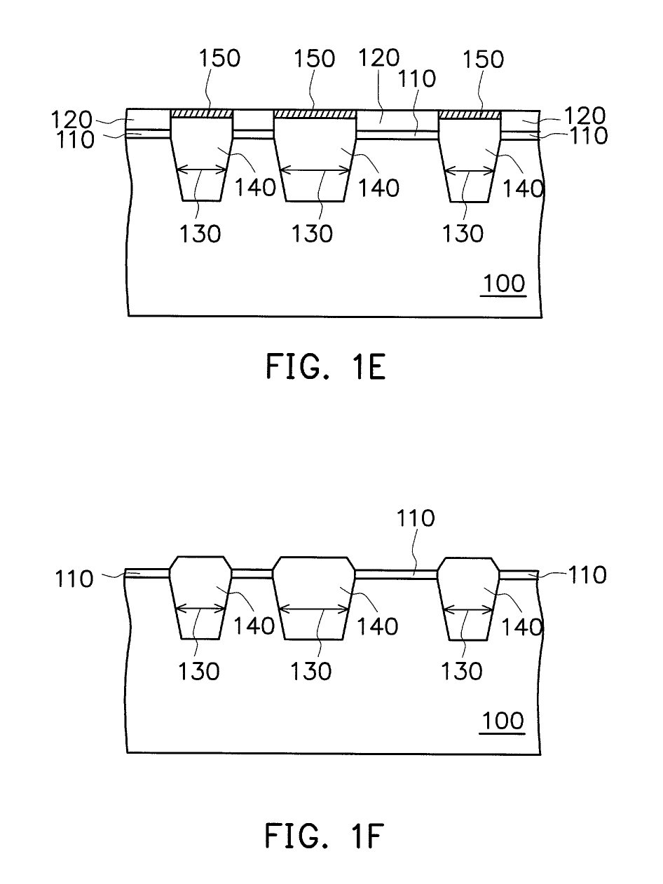

FIGS. 1A to 1F are cross-sectional views of a semiconductor device schematically illustrating a fabrication process for forming a shallow trench isolation structure according to a preferred embodiment of the invention.

In FIG. 1A, a pad oxide layer 110 and a mask layer 120 are sequentially formed on the substrate 100. The mask layer 120 and the pad oxide 110 are etched through, plus the substrate 100 is partly removed to form trenches 130 in the substrate 100. The regions between trenches 130 are active areas 105, including at least a wide active area 105a and narrow active areas 105b. The material of the mask layer 120 includes, for example, silicon nitride. The mask layer 120 can protect the active areas 105a, 105b of the substrate 100 during the etching process.

In FIG. 1B, an insulating layer 140 is formed in trenches 130 and above the mask layer 120. A minimum thickness of the insulating layer 140 in trenches 130 is a sum of the depth of trenches 130 and the thickness of the pad oxide 110. Whereas, a maximum thickness of the insulating layer 140 is the sum of depth of trenches 130, the thickness of the pad oxide 110 and the thickness of the mask layer 120. For example, when the depth of trenches 130 is about 4000 Å, the thickness of the pad oxide 110 is about 200 Å, and the thickness of the mask layer 120 is about 1600 Å, the thickness of the insulating layer 140 in trenches 130 is ranged between about 4200-5800 Å. The process window is as large as about 1600 Å in this example, and thus is easy to achieve.

The material of the insulating layer 140 includes, for example, silicon oxide, and the formation method of the insulating layer 140 includes, for example, HDPCVD. Since the high density plasma of HDPCVD has an etching effect simultaneously during deposition, the deposition rate to the etching rate ratio can thus be controlled to result in obtain vertical sidewalls 145 of the insulating layer 140 over the active regions 105 above the substrate 100. For example, by tuning process conditions, including D/S ratio about 4.0, bias (RF power) about 3000 kW, temperature about 300-380° C. and pressure about 5 mT, a vertical sidewall can be formed. Preferably, the process parameters can be further fine-tuned to obtain vertical sidewalls, as the following exemplary conditions: RF power (top): 1200-1450 W; RF power (side): 2900-3380 W; RF bias power match box (off); Ar gas flow rate: 80-135 sccm; Ar gas (top) flow rate: 10-20 sccm; O₂ gas flow rate: 188-245 sccm; O₂ gas (top) flow rate: 22-40 sccm; SiH₄ gas flow rate: 100-128 sccm; SiH₄ gas (top) flow rate: 12-22 sccm; and pressure control: T.V. setting 700-880 steps. However, the present invention is not limited by the aforementioned parameters, since these parameters are only exemplary.

A thin film 150 is formed on the insulting layer 140. The material of the thin film 150 is preferably selected from a material with good removal selectivity over the insulating layer 140. For example, when the insulating layer 140 is made of silicon oxide, the thin film 150 material can be made of silicon nitride or polysilicon. The thickness of the thin film 150 is preferably about 100 to about 500 Å, for example, about 200 Å, which is about the thickness of the pad oxide 110. The formation method of the thin film 150 is, for example, chemical vapor deposition. Due to the vertical geometry of the sidewalls 145, the thin film 150 deposited on the sidewalls 145 is thinner than that on other positions. As shown in FIG. 1B, while a sputtering step is applied instead of chemical vapor deposition, almost no thin film 150 can be formed on the sidewalls 145.

A screen layer 160 is formed by a fluid precursor to cover the thin film 150 above trenches 130. The material selected for forming the screen layer 160 includes, for example, spin-on-glass (SOG) or photoresist. These kinds of materials are typically dissolved in a solution, followed by being spin coated over the substrate 100. Therefore, the fluid material fills a recess or lower surface level before covering portions with a higher surface level. A curing step is then performed onto the screen layer 160 after spin-coating. As a result, the thin film 150 on a projecting part of the insulating layer 140 above the active regions 105 is covered by a very thin thickness of the screen layer 160. The only exception is the screen layer 160 covering the thin film 150 on a flat part of the insulating layer 140 above the wide active area 105a. In contrast, the screen layer 160 over the trenches 130 has a greater thickness compared to that over the active regions 105.

In FIG. 1C, an etching step is performed to remove only the screen layer 160 with a very thin thickness, that is, the screen layer above the narrow active areas 105b and the screen layer along the sidewalls and on the corners of the wide active area 105a. Therefore, only the screen layer 160a above the wide active area 105a and the screen layer 160b over the trenches 130 are remained. The etching step performed, for example, is a quick oxide etching step using time control.

In FIG. 1D, the thin film 150 on the mask layer 120 is removed to expose the insulating layer 140 above the mask layer 120. The screen layer 160a over the thin film 150 above the wide active area 105a is removed along with the thin film 150. If the thin film 150 is made of silicon nitride, using hot phosphoric acid as an etchant can remove the thin film 150, including the thin film under the screen layer 160a above the wide active area 105a. Because the thin film 150 under the screen layer 160a is removed, the screen layer 160a is lifted at the same time. However, the thin film 150 above the trenches are not removed because of the protection of the screen layer 160b.

In FIG. 1E, the insulating layer 140 on the mask layer 120 and the screen layer 160 above trenches 130 are respectively removed to expose the mask layer 120 and the thin film 150 remained on the trenches 130. If the insulating layer 140 is made of silicon oxide and the screen layer 160 is made of SOG, since both the materials are silicon oxide, both can be removed in one step. If the removal method used is dry etching, CF₄ plasma can be used. If the removal method used is wet etching, the HF solution can be used.

In FIG. 1F, the thin layer 150 and the mask layer 120 are removed to expose the insulating layer 140 in the trenches 130 and the substrate 100, while the insulating layer 140 is almost level with a surface of the substrate 100. If the material of the thin layer 150 and the mask layer 120 both are silicon nitride, hot H₃PO₄ can be used to remove both the thin layer 150 and the mask layer 120.

In light of the foregoing embodiment, this invention controls the surface level of the insulating layer in the trenches to be no lower than the pad oxide but no higher than the mask layer. A thin film is formed as a protection of the insulating layer filled in the trenches, plus the formation of a screen layer which further protects the thin film above the trenches, a shallow trench isolation is formed after removing the thin film, the screen layer without using CMP. Therefore, no scratches or defects will be formed on the surface of the active areas and the STI, so that the problems of poor insulation, current leakage etc. are prevented.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for forming a shallow trench isolation structure, comprising the steps of:
providing a substrate comprising at least a trench and an active region covered by a mask layer and isolated by the trench;
forming an insulation layer to fill the trenches and to cover the mask layer by high density plasma chemical vapor deposition, wherein a surface of the insulation layer is higher than a surface of the substrate and lower than a surface of the mask layer;
forming a thin film on the insulation layer;
forming a screen layer on the thin film by a fluid precursor;
removing the screen layer and the thin film over the active region, while the screen layer and the thin film above the trenches are not removed;
removing the insulating layer above the active areas to expose the mask layer;
removing the screen layer to expose the thin film in the trench;
removing the thin film above the trench to expose the insulation layer; and
removing the mask layer above the active region.

2. The method of claim 1, wherein the insulating layer includes a silicon oxide layer.

3. The method of claim 1, wherein the thin film includes a silicon nitride layer.

4. The method of claim 1, wherein the thin film includes a polysilicon layer.

5. The method of claim 1, wherein the screen layer includes a spin-on-glass layer.

6. The method of claim 1, wherein the screen layer includes a photoresist layer.

7. The method of claim 1, comprising further a step of forming a pad oxide layer on the substrate under the mask layer.

8. A method for forming a shallow trench isolation structure, comprising:
providing a substrate comprising a plurality of trenches and a plurality of active areas, wherein the active areas are covered by a pad oxide layer and a mask layer;
forming an insulation layer in the trenches and on the mask layer, wherein the insulation layer in the trenches has a surface higher than a surface of the substrate and lower than a surface of the mask layer, and wherein the insulation layer on the mask layer has vertical sidewalls;
forming a thin film on the insulation layer above the active areas and the trenches, wherein the thin film formed on the vertical sidewalls of the insulation layer is thinner than the thin film formed on other positions of the insulation layer;
forming a screen layer on the thin film by a fluid precursor, wherein a thickness of the screen layer formed above the active areas is thinner than a thickness of the screen layer formed above the trenches;
removing the screen layer and the thin film above the active areas, while the screen layer and the thin film above the trenches are not removed;
removing the insulating layer above the active areas;
removing the screen layer above the trenches;
removing the thin film above the trenches; and
removing the mask layer above the active areas.

9. The method of claim 8, wherein the insulating layer includes a silicon oxide layer.

10. The method of claim 8, wherein the thin film includes a silicon nitride layer.

11. The method of claim 8, wherein the thin film includes a polysilicon layer.

12. The method of claim 8, wherein the screen layer includes a spin-on-glass layer.

13. The method of claim 8, wherein the screen layer includes a photoresist layer.

14. A method for forming a shallow trench isolation structure, applicable to a substrate having at least an active area on the substrate, at least a trenches surrounding the active area, and a pad oxide layer and a mask layer formed sequentially on the substrate in the active area, the method comprising:
forming an insulation layer in the trenches and on the mask layer, wherein the insulation layer in the trench has a thickness ranged between a sum of a depth of the trench and a thickness of the pad oxide and a sum of the depth of the trench plus a thickness of both the mask layer and the pad oxide layer;
forming a thin layer on the insulation layer;
forming a screen layer on the thin layer above the trenches;
removing the thin layer above the mask layer and above the active area, while the screen layer and the thin layer above the trenches are not removed;
removing the insulating layer above the mask layer and above the active area;
removing the screen layer above the trenches;
removing the thin layer above the trenches; and
removing the mask layer above the active areas.

15. The method of claim 14, wherein the insulating layer includes a silicon oxide layer.

16. The method of claim 14, wherein the thin layer includes a silicon nitride layer.

17. The method of claim 14, wherein the thin layer includes a polysilicon layer.

18. The method of claim 14, wherein the screen layer includes a spin-on-glass layer.

19. The method of claim 14, wherein the screen layer includes a photoresist layer.

20. The method of claim 14, wherein the insulation layer is formed with a vertical sidewall by controlling an etching/deposition ratio of a high density plasma chemical vapor deposition step.
